(19) United States
(12) Patent Application Publication
(10) Pub. No.: US 2013/0090446 A1
(43) Pub. Date: Apr. 11, 2013

(54) POLYMER CONTAINING UNITS OF FLUORENE, ANTHRACENE AND BENZOTHIADIAZOLE, PREPARATION METHOD THEREOF AND APPLICATION THEREOF

(71) Applicants: Mingjie Zhou, Guangdong (CN); Jie Huang, Guangdong (CN); Jiale Huang, Guangdong (CN)

(72) Inventors: Mingjie Zhou, Guangdong (CN); Jie Huang, Guangdong (CN); Jiale Huang, Guangdong (CN)

(21) Appl. No.: 13/704,674

(22) PCT Filed: Jun. 23, 2010
(86) PCT No.: PCT/CN10/74320

§ 371 Date: Dec. 17, 2012

(51) Int. Cl. C08G 75/32

(52) U.S. Cl. CPC C08G 75/32
USPC 528/8

(57) ABSTRACT

A polymer containing units of fluorene, anthracene and benzothiadiazole with the following formula is provided:

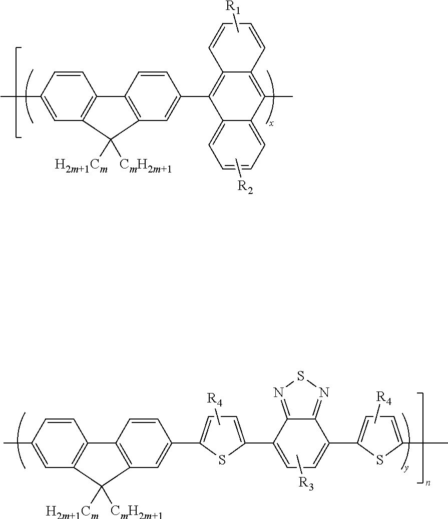

2,7-bis(4,4,5,5-tetramethyl-1,3,2-dioxaborolanyl)-9,9-dialkylfluorene, 9,10-dibromoanthracene or its or derivatives and 4,7-bis(5′-bromo-2′-thienyl)-2,1,3-benzothiadiazole or its derivatives are added to solvent, after the catalyst and base solution are added to the solution, the compounds in the solution are processed by Suzuki coupling reaction to obtain polymer. This kind of polymer containing units of fluorene, anthracene and benzothiadiazole have low energy gap, high mobility of the carriers, wide range of spectral absorption and have a broad prospect of application in the field of photoelectric.

### FIELD OF THE INVENTION

The present disclosure relates to optoelectronic technology, and more particularly relates to a polymer containing units of fluorene, anthracene and benzothiadiazole, preparation method thereof and application thereof.

### BACKGROUND OF THE INVENTION

The raw material of the traditional solar cell device with high-efficiency is mainly inorganic semiconductor silicon. However, the complex of the production process, serious pollution, energy consumption, high cost of the silicon solar cells inhibit the development of its commercial applications. The preparation of low-cost and high-energy solar cells by using cheap materials has been a research hotspot and difficulty in the photovoltaic field. On one hand, because the organic materials have good environment stability, low production cost, regulation function easily, flexibility and good film forming properties; on the other hand, because the preparation process of organic solar cell is relatively simple, low operation temperature, low device fabrication cost. The organic semiconductor material has attracted much attention and has become the solar cell materials with low cost and attractive. In addition, the organic solar cell has some advantages such as it can be prepared in large areas and use flexible substrates, and it is environmentally friendly and portable.

Organic photovoltaic material has the following advantages: good thermal stability, processing easily, low cost and specific optoelectronic functions can be achieved by molecular design. Anthracene and its derivatives have good stability and good film-forming properties; their UV-visible spectroscopy show wide finger peak absorption, which is conducive to improve the absorption of sunlight; in addition, anthracene and its derivatives have appropriate carrier transport characteristics, and the hole mobility of the crystal at room temperature can reach to 3 cm²/V·s, anthracene and its derivatives are excellent organic semiconductor materials. Although there are many reports about anthracene and its derivatives as organic electroluminescent materials, but anthracene and its derivatives as an organic photovoltaic material have rarely been reported, which greatly limit the scope of their application.

### SUMMARY OF THE INVENTION

In one aspect of the present disclosure, an organic photovoltaics compounds containing anthracene unit is desired.

In addition, in another aspect of the present disclosure, a preparation method and application of the organic photovoltaics compounds containing anthracene unit is also desired.

A polymer containing units of fluorene, anthracene and benzothiadiazole has the following formula:

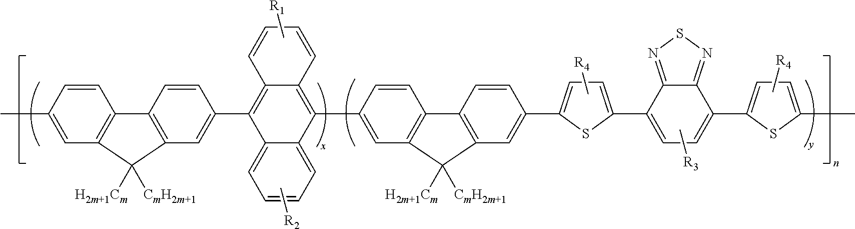

wherein n represents an integer between 1 and 200, m represents an integer between 1 and 20; x, y are positive real numbers, and x+y=1; R₁, R₂ represent H, halogen, cyano, C₁ to C₄₀ alkyl, C₁ to C₄₀ aryl or C₁ to C₄₀ heteroaryl; R₃, R₄ represent H, halogen, cyano, C₁ to C₄₀ alkyl, C₁ to C₄₀ alkoxy, C₆ to C₄₀ aryl, C₆ to C₄₀ aralkyl or C₆ to C₄₀ arylalkoxy.

R₁, R₂, R₃, R₄ described above can represent mono-substituted functional group or multi-substituted functional group, for example, R₁ can represent two substituents, three substituents, and so on.

A preparation method of a polymer containing units of fluorene, anthracene and benzothiadiazole, includes the following steps:

S11, compounds A, B and C represented by the following formulas are provided, respectively,

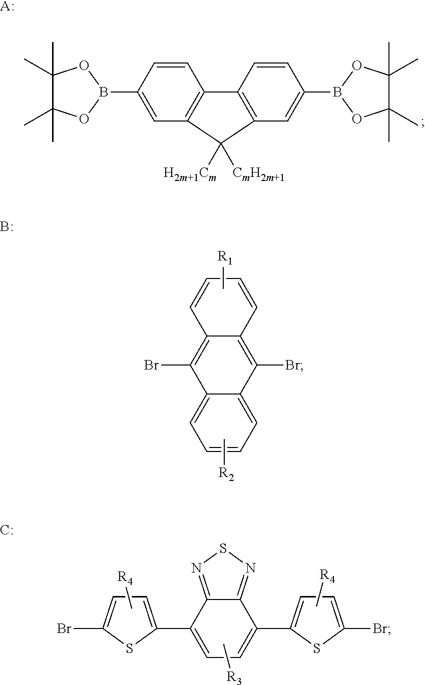

wherein m represents an integer between 1 and 20;
S12, under the condition of oxygen-free environment, compounds A, B and C are subjected to a Suzuki coupling reaction in the presence of organic solvent, catalyst and alkaline solution to obtain the polymer containing units of fluorene, anthracene and benzothiadiazole with the following formula:

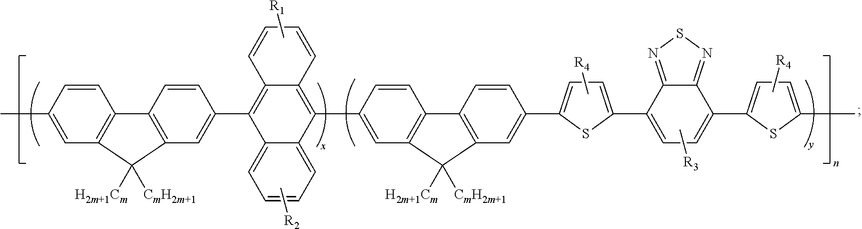

wherein n represents an integer between 1 and 200; m represents an integer between 1 and 20;
x, y are positive real numbers, and x+y=1;
R₁, R₂ represent H, halogen, cyano, C₁ to C₄₀ alkyl, C₁ to C₄₀ aryl or C₁ to C₄₀ heteroaryl;
R₃, R₄ represent H, halogen, cyano, C₁ to C₄₀ alkyl, C₁ to C₄₀ alkoxy, C₆ to C₄₀ aryl, C₆ to C₄₀ aralkyl or C₆ to C₄₀ arylalkoxy.

Preferably, in step 51, compound A is prepared by the following steps: compounds D and E represented by the following formulas are provided, respectively,

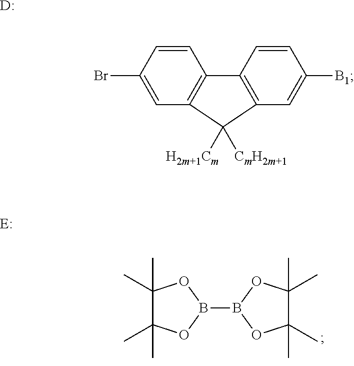

wherein m represents an integer between 1 and 20;
under conditions of anhydrous and oxygen-free environment, compound D is added to the solvent at a temperature of −70° C. to −85° C., n-butyl lithium is added to solution according to a molar ratio of the n-butyl lithium to the compound D of 2:1 to 4:1, and then the solution is stirred for 2 hours; the solvent is at least one selected from the group consisting of tetrahydrofuran, diethyl ether, dichloromethane, chloroform, and ethyl acetate;
compound E is added to the solution according to a molar ratio of the compound E to the compound D of 2:1 to 4:1, the temperature is raised to room temperature, after the reaction lasted for 12 to 48 hours, the compound A represented by the following formula is obtained:

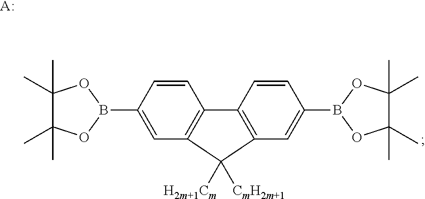

wherein m represents an integer between 1 and 20.

Preferably, in step S12, the solvent is at least one selected from the group consisting of toluene, ethylene glycol, dimethyl ether, tetrahydrofuran, diethyl ether, dichloromethane, chloroform and ethyl acetate; the added amount of alkali solution is 5 to 10 times of a molar amount of the compound A; the added amount of catalyst is 0.5% to 10% of a molar amount of compound A; the catalyst is organic palladium catalyst or a mixture of organic palladium and organic phosphine ligand; the alkali solution is NaOH aqueous solution, Na₂CO₃ aqueous solution, NaHCO₃ aqueous solution or tetraethyl ammonium hydroxide aqueous solution, the temperature of the Suzuki coupling reaction is 60 to 100° C., the reaction time is 12 to 72 hours.

Preferably, a molar ratio of the organic palladium to the organic phosphine ligand is 1:2 to 1:20 in the mixture of organic palladium and organic phosphine ligand; the organic palladium is Pd₂(dba)₃, Pd(PPh₃)₄ or Pd(PPh₃)₂Cl₂; the organic phosphine ligand is P(o-Tol)₃.

Preferably, the preparation method further includes the purification process after the polymer is obtained, the purification steps comprise:

S13, the deionized water and toluene are added to the polymer obtained in step S12 to extract the polymer, the organic phase is extracted and distilled under reduced pressure, and then add the organic phase dropwise to the anhydrous methanol with stirring constantly, and then the solid is precipitated from the solution, the solid is pumping filtrated and dried to obtain the solid powder, and then the solid powder is dissolved in chloroform and purified by column chromatography of neutral alumina, after the catalyst is removed, the solution was rotary evaporated, and then add the solution dropwise to the methanol solvent with stirring, finally the solution is extracted by Soxhlet extraction to obtain a purified polymer.

A solar cell device using the polymer described above includes a substrate, a conductive layer deposited on one surface of the substrate serving as an anode, a poly 3,4-ethylenedioxy thiophene: polystyrene sulfonic acid layer coated on the conductive layer functioning for modification; an active layer coated on the surface of the poly 3,4-ethylenedioxy thiophene: polystyrene sulfonic acid layer, and an aluminum layer coated on the active layer serving as a cathode; the material of the active layer is mixture which includes electron donor materials and electron acceptor materials; the electron acceptor material is [6,6]-phenyl-C61-butyric acid methyl ester, the electron donor material includes the polymer containing units of fluorene, anthracene and benzothiadiazole described above.

An organic light-emitting device using the polymer described above includes a substrate, a conductive layer deposited on one surface of the substrate serving as an anode, a luminescent layer coated on the conductive layer, a buffer layer deposited on the surface of the luminescent layer, and an aluminum layer coated on the buffer layer serving as a cathode, the buffer layer is deposited by evaporation and the material of the buffer layer is LiF, the material of the luminescent layer includes the polymer containing units of fluorene, anthracene and benzothiadiazole described above.

An organic field-effect transistor using the polymer described above includes a doping silicon wafer, a SiO₂ insulation layer, an octadecyltrichlorosilane layer for modifying the SiO₂ insulation layer, an organic semiconductor layer coated on the octadecyltrichlorosilane layer, a source electrode and a drain electrode interval disposed on the organic semiconductor layer, which are laminated in this order, the material of the organic semiconductor layer includes the polymer containing units of fluorene, anthracene and benzothiadiazole described above.

Anthracene and its derivatives have good stability and good film-forming properties; their UV-visible spectroscopy shows wide finger peak absorption, which is contributive to improve the absorption of sunlight, in addition, anthracene and its derivatives have appropriate carrier transport characteristics, and the hole mobility of the crystal at room temperature can reach to 3 cm²/V·s, thus making them a kind of excellent organic semiconductor materials. The compound containing fluorene has the structure which can be modified easily, and the compound containing fluorene has a good light and heat stability and film forming properties.

The polymer containing units of fluorene, anthracene and benzothiadiazole has a low energy gap, high mobility, and a wide absorption range of the spectrum, in addition, the carriers within the active layer material can transmit more efficiently due to the polymer.

### BRIEF DESCRIPTION OF THE DRAWINGS

FIG. 1 is a schematic view of a solar cell device according to an embodiment;

FIG. 2 a schematic view of an organic electroluminescent device according to an embodiment;

FIG. 3 a schematic view of an organic field-effect transistor according to an embodiment.

### DETAILED DESCRIPTION

The objective of the present invention is to provide a polymer containing units of fluorene, anthracene and benzothiadiazole and its preparation method, and to disclose the application of the polymer material in the photoelectric field.

A polymer containing units of fluorene, anthracene and benzothiadiazole has the following formula:

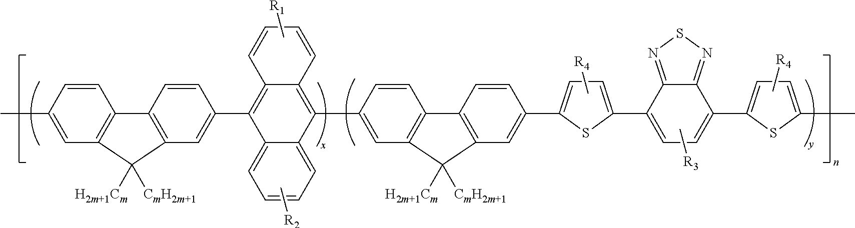

wherein n represents an integer between 1 and 200, m represents an integer between 1 and 20; x, y are positive real numbers, and x+y=1; R₁, R₂ represent H, halogen, cyano, C₁ to C₄₀ alkyl, C₁ to C₄₀ aryl or C₁ to C₄₀ heteroaryl; R₃, R₄ represent H, halogen, cyano, C₁ to C₄₀ alkyl, C₁ to C₄₀ alkoxy, C₆ to C₄₀ aryl, C₆ to C₄₀ aralkyl or C₆ to C₄₀ arylalkoxy.

R₁, R₂, R₃, R₄ described above can represent mono-substituted functional group or multi-substituted functional group, for example, R₁ can represent two substituents, three substituents, and so on.

A preparation method of a polymer containing units of fluorene, anthracene and benzothiadiazole, includes the following steps:

Step One

Compounds D and E represented by the following formulas are provided, respectively:

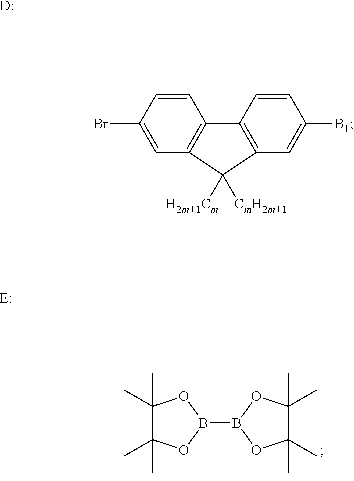

wherein m represents an integer between 1 and 20;
under a temperature of −70° C. to −85° C., under conditions of anhydrous and oxygen-free environment, the compound D is added to the solvent, the n-butyl lithium is added according to a molar ratio of the n-butyl lithium to the compound D of 2:1 to 4:1, the solution is stirred for 2 hours; the solvent is at least one selected from the group consisting of tetrahydrofuran, diethyl ether, dichloromethane, chloroform, and ethyl acetate;
the compound E is added to the solution according to a molar ratio of the compound E to the compound D of 2:1 to 4:1, the temperature is raised to room temperature, after the reaction lasted for 12 to 48 hours, the compound A represented by the following formula is obtained:

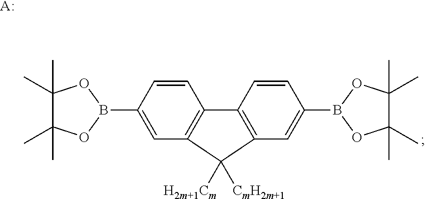

wherein m represents an integer between 1 and 20.

Step Two

Compounds A, B and C represented by the following formulas are provided, respectively,

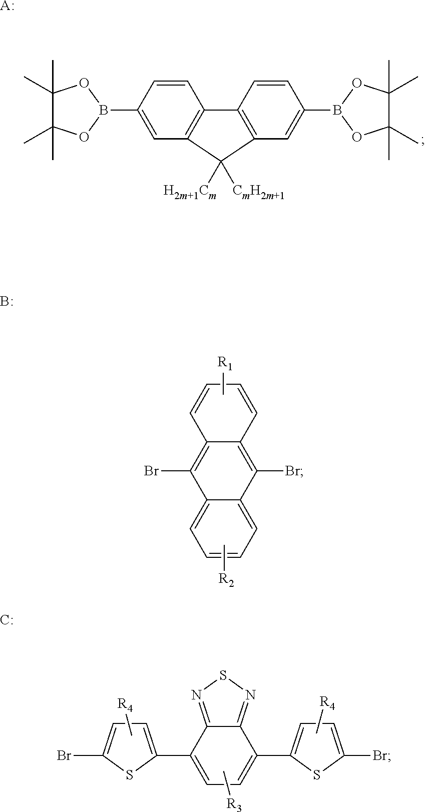

wherein m represents an integer between 1 and 20;
under the oxygen-free environment, compounds A, B and C are subjected to a Suzuki coupling reaction in the presence of organic solvent, catalyst and alkaline solution to obtain the polymer containing units of fluorene, anthracene and benzothiadiazole with the following formula:

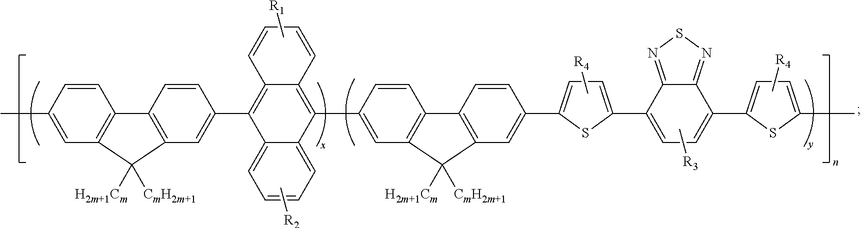

wherein n represents an integer between 1 and 200; m represents an integer between 1 and 20;
x, y are positive real numbers, and x+y=1;
R₁, R₂ represent H, halogen, cyano, C₁ to C₄₀ alkyl, C₁ to C₄₀ aryl or C₁ to C₄₀ heteroaryl;
R₃, R₄ represent H, halogen, cyano, C₁ to C₄₀ alkyl, C₁ to C₄₀ alkoxy, C₆ to C₄₀ aryl, C₆ to C₄₀ aralkyl or C₆ to C₄₀ arylalkoxy.

R₁, R₂, R₃, R₄ described above can represent mono-substituted functional group or multi-substituted functional group, for example, R₁ can represent two substituents, three substituents, and so on.

Preferably, in step two, the solvent is at least one selected from the group consisting of toluene, ethylene glycol, dimethyl ether, tetrahydrofuran, diethyl ether, dichloromethane, chloroform and ethyl acetate; the added amount of catalyst is 0.5% to 10% of a molar amount of compound A; the catalyst is organic palladium catalyst or a mixture of organic palladium and organic phosphine ligand; the added amount of alkali solution is 5 to 10 times of a molar amount of the compound A; the alkali solution is NaOH aqueous solution, Na₂CO₃ aqueous solution, NaHCO₃ aqueous solution or tetraethyl ammonium hydroxide aqueous solution; the temperature of the Suzuki coupling reaction is 60 to 100° C., the reaction time is 12 to 72 hours.

Preferably, a molar ratio of the organic palladium to the organic phosphine ligand is 1:2 to 1:20 in the mixture of organic palladium and organic phosphine ligand; the organic palladium is Pd₂(dba)₃, Pd(PPh₃)₄ or Pd(PPh₃)₂Cl₂; the organic phosphine ligand is P(o-Tol)₃.

In a specific embodiment, the oxygen-free condition described above can be achieved by means of nitrogen or inert gas protection.

Step three The deionized water and toluene are added to the polymer obtained to extract the polymer, the organic phase is extracted and distilled under reduced pressure, and then add the organic phase dropwise to the anhydrous methanol with stirring constantly, and then the solid is precipitated from the solution, the solid is pumping filtrated and dried to obtain the solid powder, and then the solid powder is dissolved in chloroform and then purified by column chromatography of neutral alumina, after the catalyst is removed, the solution was rotary evaporated, and then add the solution dropwise to the methanol solvent with stirring, finally the solution is extracted by Soxhlet extraction to obtain a purified polymer.

The following specific embodiments are provided for further illustrate of the polymer, the preparation method of the polymer and its applications.

### Example 1

The polymer is disclosed representing by the following formula:

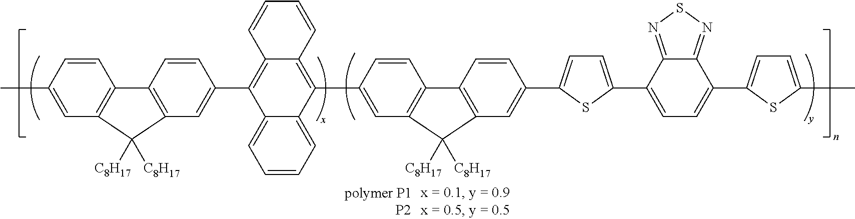

the preparation process of the polymer described above is as follows:
firstly, the preparation of 2,7-bis(4,4,5,5-tetramethyl-1,3,2-dioxaborolan-2-yl)-9,9-dioctylfluorene:

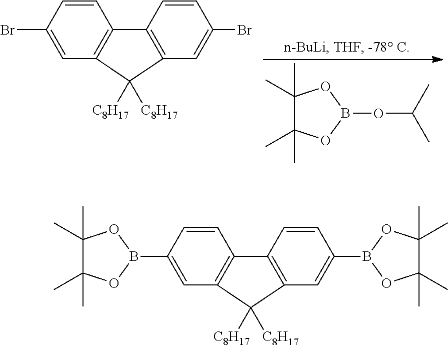

the anhydrous and oxygen-free reaction devices were assembled, 9.0 mmol of white 2,7-dibromo-9,9-dioctylfluorene was added to the 3-neck flask under continuous agitation and the protection of N₂, 150 ml of purified tetrahydrofuran solvent was injected with a syringe, 27.0 mmol of n-BuLi was injected slowly at −78° C. with a syringe, and then the solution was stirred and reacted for 2 hours. After reacting for 2 hours, 30.6 mmol of 2-isopropoxy-4,4,5,5-tetramethyl-1,3,2-dioxaborolane was injected with a syringe at −78° C., the temperature was raised to room temperature and the mixture reacted over night.

After the reaction was finished, saturated NaCl aqueous solution was added to the solution, and the solution was extracted by chloroform, dried by anhydrous sodium sulfate, pumping filtered, and then the filtrate was collected and the solvent was rotary evaporated off. Finally the raw product was subjected to silica gel column chromatography separation with petroleum ether: ethyl acetate (v/v=15:1) as eluent to obtain the solid powder 2,7-bis(4,4,5,5-tetramethyl-1,3,2-dioxaborolan-2-yl)-9,9-dioctylfluorene, the yield of the product was 65%. GC-MS (EI-m/z): 642 (M⁺).

Secondly, the preparation of the compounds with the following formulas

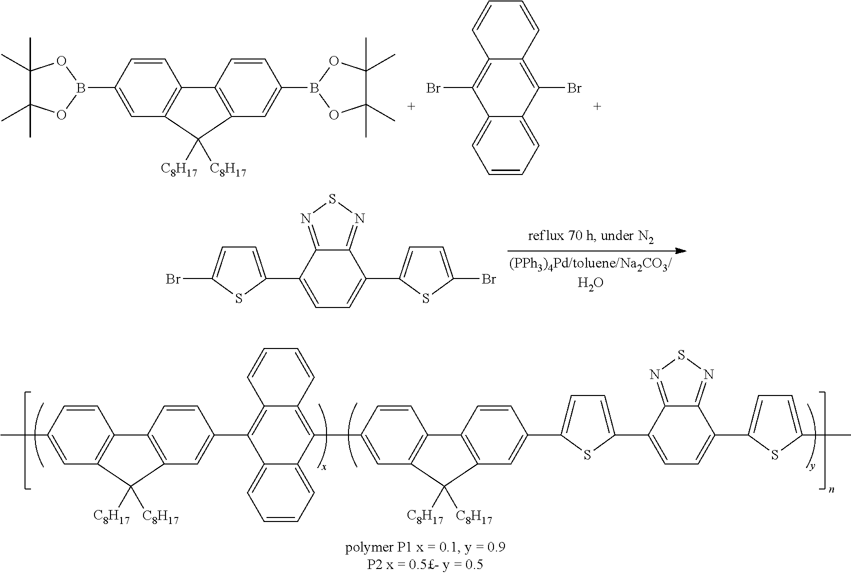

The Preparation of P1

1 mmol of 2,7-bis(4,4,5,5-tetramethyl-1,3,2-dioxaborolan-2-yl)-9,9-dioctylfluorene, 0.1 mmol of 9,10-dibromoanthracene, 0.9 mmol of 4,7-bis(5′-bromo-2′-thienyl)-2,1,3-benzothiadiazole, 0.025 mmol of tetrakis (triphenylphosphine) palladium, 5 ml of 2 mol/L Na₂CO₃ aqueous solution and 30 ml of toluene solvent were added to the reactor, the reaction system was kept in oxygen-free condition by purging N₂ and vacuum pumping repeatedly, at 90° C., the reaction lasted for 70 hours.

After 70 hours, the deionized water and toluene were added to the reactor containing the product to extract the polymer, the organic phase was extracted, and the polymer/toluene was distilled to about 5 ml under reduced pressure, and then added the organic phase dropwise to 300 ml of anhydrous methanol with stirring constantly, and the solid was precipitated from the solution, the solid was pumping filtrated and dried to obtain the solid powder. And then the solid powder was dissolved in chloroform and purified by column chromatography of neutral alumina, after the catalyst tetrakis (triphenylphosphine) palladium was removed, the volume of the polymer/chloroform solution was reduced to about 5 ml by rotary evaporation, the solution was added dropwise to the methanol solvent and stirred several hours, and then the polymer P1 was collected and dried. The polymer was extracted by Soxhlet extraction, sequentially the monodispersity of the polymer molecular weight of the polymer was improved.

The purified polymer P1 was subject to GPC measurement, the number average molecular weight Mn≈52400, polymer monodisperse was 2.45.

The Preparation of P2

1 mmol of 2,7-bis(4,4,5,5-tetramethyl-1,3,2-dioxaborolan-2-yl)-9,9-dioctylfluorene, 0.5 mmol of 9,10-dibromoanthracene and 0.5 mmol of 4,7-bis(5′-bromo-2′-thienyl)-2,1,3-benzothiadiazole were added to the reactor, the amount of other materials added, reaction conditions and post-treatment methods were similar to the preparation of P1, finally, the polymer P2 was obtained. The purified polymer P2 was subject to GPC measurement, the number average molecular weight Mn≈41700, polymer monodisperse was 2.16.

### Example 2

The polymer is disclosed representing by the following formula:

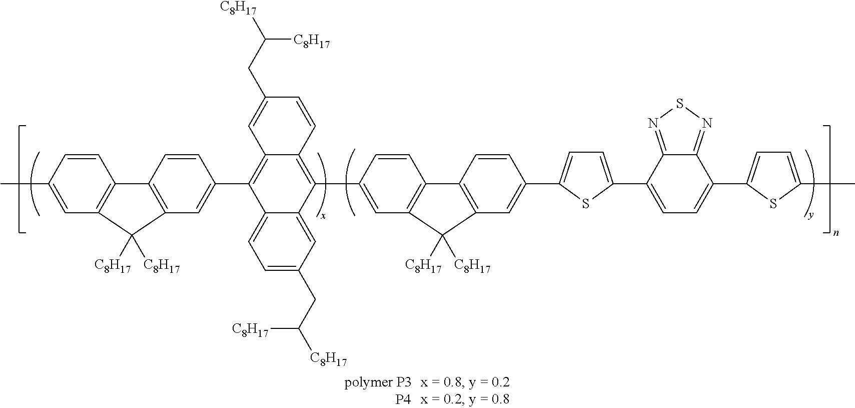

the preparation process of the polymer described above is as follows:
firstly, the preparation of 2,7-bis(4,4,5,5-tetramethyl-1,3,2-dioxaborolan-2-yl)-9,9-dioctylfluorene:

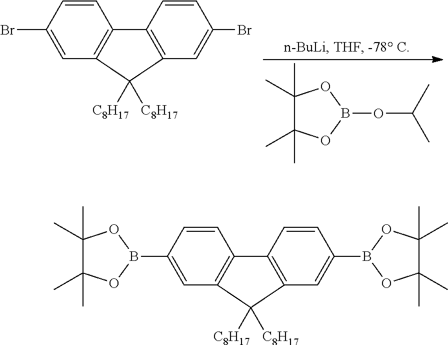

the anhydrous and oxygen-free reaction devices were assembled, 9.0 mmol of white 2,7-dibromo-9,9-dioctylfluorene was added to the 3-neck flask under continuous agitation and the protection of N₂, 150 ml of purified tetrahydrofuran solvent was injected with a syringe, 27.0 mmol of n-BuLi was injected slowly at −78° C. with a syringe, and then the solution was stirred and reacted for 2 hours. After reacting for 2 hours, 30.6 mmol of 2-isopropoxy-4,4,5,5-tetramethyl-1,3,2-dioxaborolane was injected with a syringe at −78° C., the temperature was raised to room temperature and the mixture reacted over night.

After the reaction is finished, saturated NaCl aqueous solution was added, and the solution extracted by chloroform, dried by anhydrous sodium sulfate, pumping filtered, and then the filtrate was collected and the solvent was rotary evaporated off. Finally the raw product was subjected to silica gel column chromatography separation with petroleum ether: ethyl acetate (v/v=15:1) as eluent to obtain the solid powder 2,7-bis(4,4,5,5-tetramethyl-1,3,2-dioxaborolan-2-yl)-9,9-dioctylfluorene, the yield of the product was 65%. GC-MS (EI-m/z): 642 (M⁺).

Secondly, the preparation of the compounds with the following formulas.

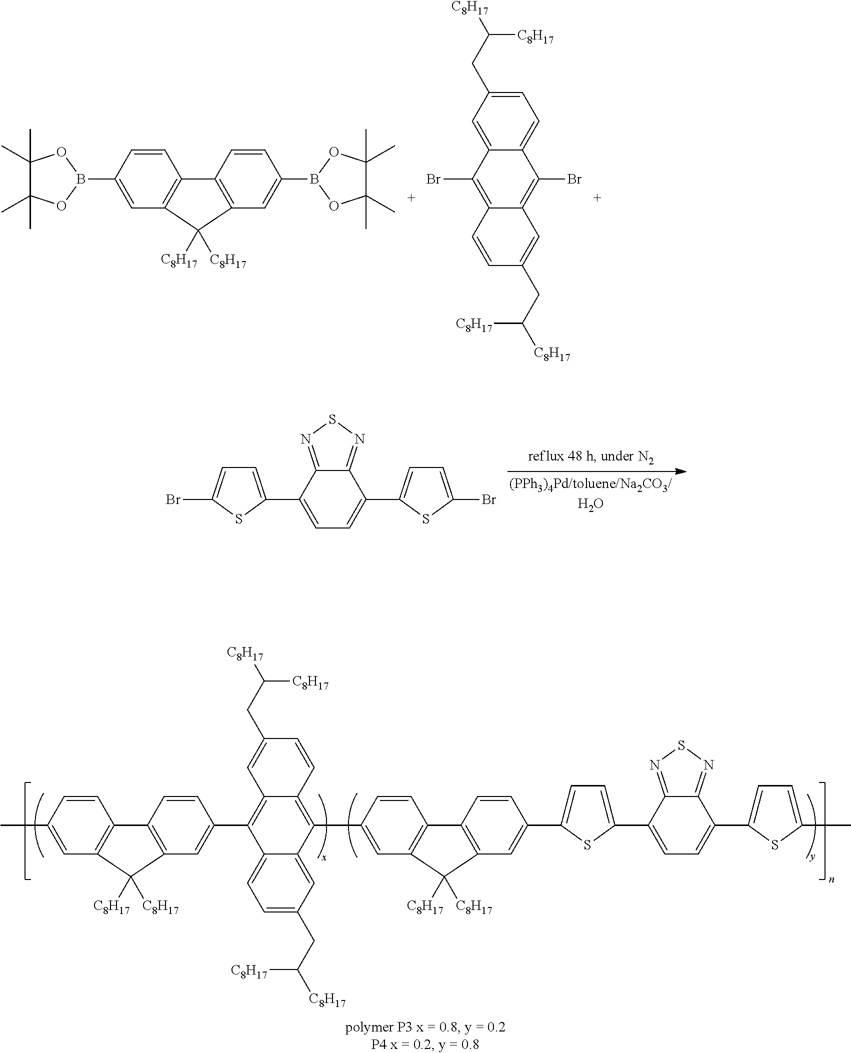

The Preparation of P3

1 mmol of 2,7-bis(4,4,5,5-tetramethyl-1,3,2-dioxaborolan-2-yl)-9,9-dioctylfluorene, 0.8 mmol of 9,10-dibromo-2,6-bis(2-octyl decyl) anthracene (The preparation process of the compound can be referred by: Macromol. Chem. Phys. [symbol] Klaus Mullen etc., 2006, 207, 1107-1115), 0.2 mmol of 4,7-bis(5′-bromo-2′-thienyl)-2,1,3-benzothiadiazole, 0.02 mmol of tetrakis (triphenylphosphine) palladium, 10 ml of 2 mol/L Na₂CO₃ aqueous solution and 40 ml of toluene solvent were added to the reactor, the reaction system was kept in oxygen-free condition by purging N₂ and vacuum pumping repeatedly. At 85° C., the reaction lasted for 48 hours.

After 48 hours, the deionized water and toluene were added to the reactor to extract the polymer. The organic phase was extracted, and the polymer/toluene was distilled to a little under reduced pressure, and then added the organic phase dropwise to 300 ml of anhydrous methanol with stirring constantly, and then the solid was precipitated from the solution, the solid was pumping filtrated and dried to obtain the solid powder. And then the solid powder was dissolved in chloroform and then purified by column chromatography of neutral alumina, after the catalyst tetrakis (triphenylphosphine) palladium was removed, the volume of the polymer/chloroform solution was reduced to about 5 ml by rotary evaporation, the solution was added dropwise to the methanol solvent and stirred several hours, and then the polymer P3 was collected and dried. The polymer was extracted by Soxhlet extraction, sequentially the monodispersity of the polymer molecular weight of the polymer was improved.

The polymer purified P3 was subject to GPC measurement, the number average molecular weight Mn≈35100, polymer monodisperse was 1.97.

The Preparation of P4

1 mmol of 2,7-bis(4,4,5,5-tetramethyl-1,3,2-dioxaborolan-2-yl)-9,9-dioctylfluorene, 0.2 mmol of 9,10-dibromo-2,6-bis(2-octyl decyl) anthracene and 0.8 mmol of 4,7-bis(5′-bromo-2′-thienyl)-2,1,3-benzothiadiazole were added to the reactor, the amount of other materials added, reaction conditions and post-treatment methods were similar to the preparation of P3, finally, the polymer P4 was obtained. The purified polymer P4 was subject to GPC measurement, the number average molecular weight Mn≈38600, polymer monodisperse was 1.88.

### Example 3

The polymer is disclosed representing by the following formula:

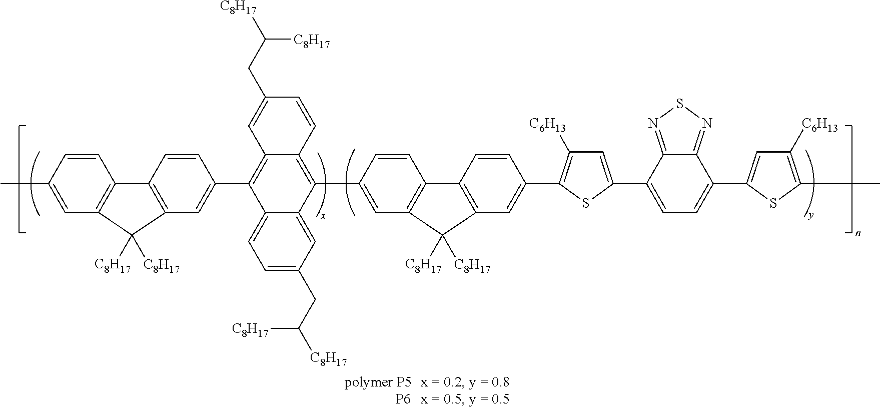

the preparation process of the polymer is as follows:
firstly, the preparation of 2,7-bis(4,4,5,5-tetramethyl-1,3,2-dioxaborolan-2-yl)-9,9-dioctylfluorene:

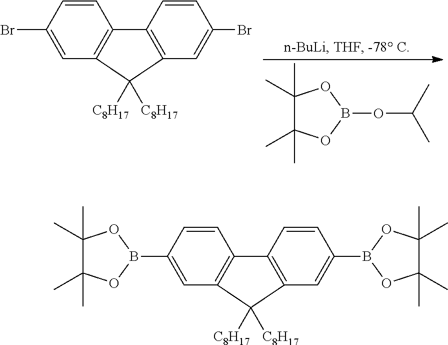

the anhydrous and oxygen-free reaction devices were assembled, 9.0 mmol of white 2,7-dibromo-9,9-dioctylfluorene was added to the 3-neck flask under continuous agitation and the protection of N₂, 150 ml of purified tetrahydrofuran solvent was injected with a syringe, 27.0 mmol of n-BuLi was injected slowly at −78° C. with a syringe, and then the solution was stirred and reacted for 2 hours. After reacting for 2 hours, 30.6 mmol of 2-isopropoxy-4,4,5,5-tetramethyl-1,3,2-dioxaborolane was injected with a syringe at −78° C., the temperature was raised to room temperature and the mixture reacted over night.

After the reaction was finished, saturated NaCl aqueous solution was added to the solution, and the solution was extracted by chloroform, dried by anhydrous sodium sulfate, pumping filtered, and then the filtrate was collected and the solvent was rotary evaporated off. Finally the raw product was subjected to silica gel column chromatography separation with petroleum ether: ethyl acetate (v/v=15:1) as eluent to obtain the solid powder 2,7-bis(4,4,5,5-tetramethyl-1,3,2-dioxaborolan-2-yl)-9,9-dioctylfluorene, the yield of the product was 65%. GC-MS (EI-m/z): 642 (M).

Secondly, the preparation of the compounds with the following formulas.

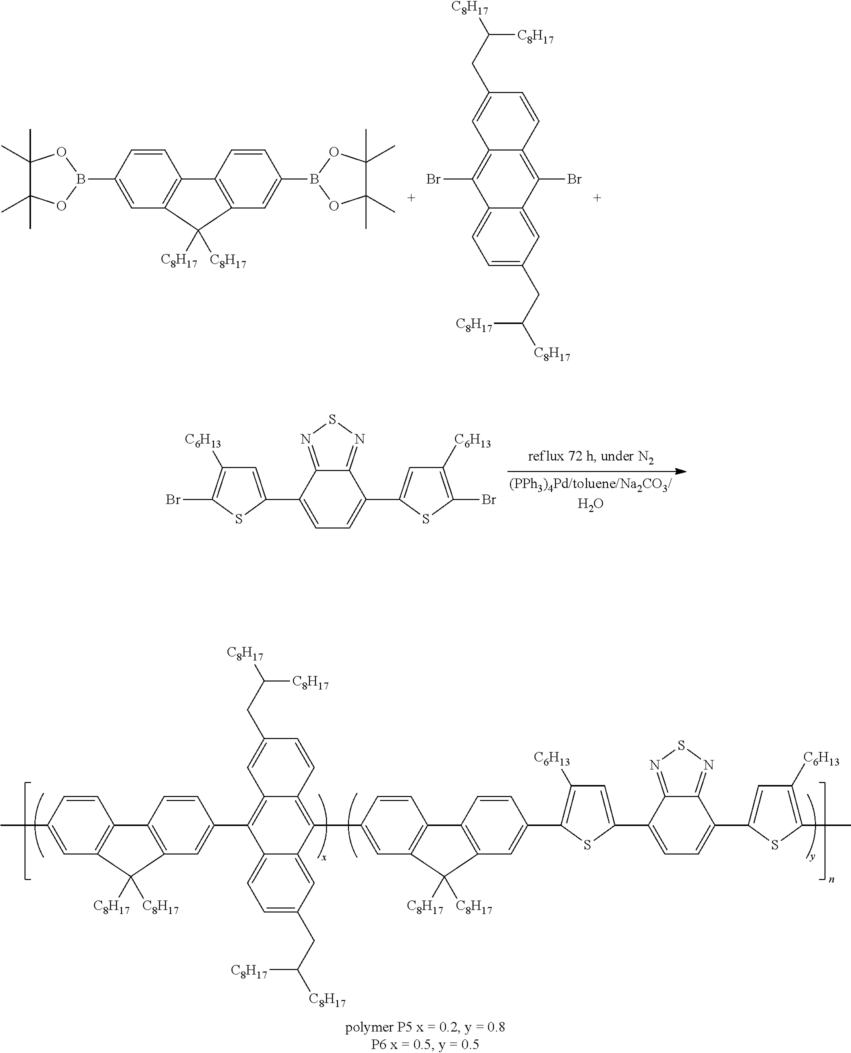

The Preparation of P5

1 mmol of 2,7-bis(4,4,5,5-tetramethyl-1,3,2-dioxaborolan-2-yl)-9,9-dioctylfluorene, 0.2 mmol of 9,10-dibromo-2,6-bis(2-octyl decyl) anthracene, 0.8 mmol of 4,7-bis(5′-bromo-4′-hexyl-2′-thienyl)-2,1,3-benzothiadiazole, 0.022 mmol of tetrakis (triphenylphosphine) palladium, 10 ml of 2 mol/L Na₂CO₃ aqueous solution and 40 ml of toluene solvent were added to the reactor, the reaction system was kept in oxygen-free condition by purging N₂ and vacuum pumping repeatedly, at 90° C., the reaction lasted for 72 hours.

After 72 hours, the deionized water and toluene were added to the reactor containing the product to extract the polymer, the organic phase was extracted, and the polymer/toluene was distilled to about 5 ml under reduced pressure, and then added the organic phase dropwise to 300 ml of anhydrous methanol with stirring constantly, and the solid was precipitated from the solution, the solid was pumping filtrated and dried to obtain the solid powder. And then the solid powder was dissolved in chloroform and purified by column chromatography of neutral alumina, after the catalyst tetrakis (triphenylphosphine) palladium was removed, the volume of the polymer/chloroform solution was reduced to about 5 ml by rotary evaporation, the solution was added dropwise to the methanol solvent and stirred several hours, and then the polymer P5 was collected and dried. The polymer was extracted by Soxhlet extraction, sequentially the monodispersity of the polymer molecular weight of the polymer was improved.

The purified polymer P5 was subject to GPC measurement, the number average molecular weight Mn≈71400, polymer monodisperse was 2.65.

The Preparation of P6

1 mmol of 2,7-bis(4,4,5,5-tetramethyl-1,3,2-dioxaborolan-2-yl)-9,9-dioctylfluorene, 0.5 mmol of 9,10-dibromo-2,6-bis(2-octyl decyl) anthracene and 0.5 mmol of 4,7-bis(5′-bromo-4′-hexyl-2′-thienyl)-2,1,3-benzothiadiazole were added to the reactor, the amount of other materials added, reaction conditions and post-treatment methods were similar to the preparation of P5, finally, the polymer P6 was obtained. The purified polymer P6 was subject to GPC measurement, the number average molecular weight Mn≈65700, polymer monodisperse was 2.28.

### Example 4

The polymer is disclosed representing by the following formula:

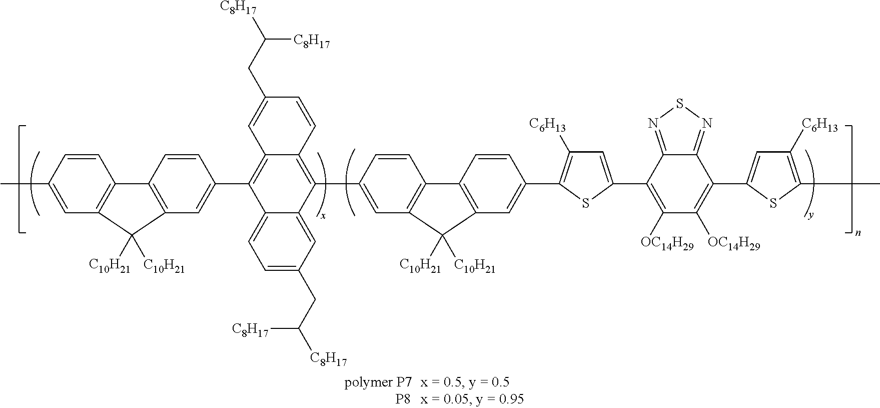

the preparation process of the polymer is as follows:
firstly, the preparation of 2,7-bis(4,4,5,5-tetramethyl-1,3,2-dioxaborolan-2-yl)-9,9-didecylfluorene:

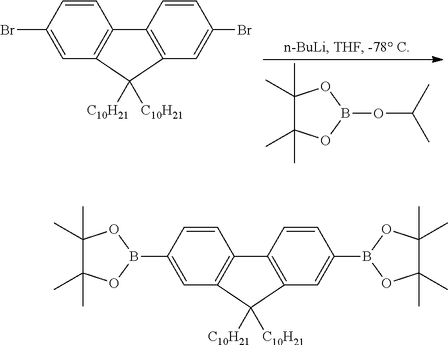

the anhydrous and oxygen-free reaction devices were assembled, 9.0 mmol of white 2,7-dibromo-9,9-didecylfluorene was added to the 3-neck flask under continuous agitation and the protection of N₂, 200 ml of purified tetrahydrofuran solvent was injected with a syringe, 25.0 mmol of n-BuLi was injected slowly at −78° C. with a syringe, and then the solution was stirred and reacted for 2 hours.

After reacting for 2 hours, 28.0 mmol of 2-isopropoxy-4,4,5,5-tetramethyl-1,3,2-dioxaborolane was injected with a syringe at −78° C., the temperature was raised to room temperature and the mixture reacted over night.

After the reaction was finished, saturated NaCl aqueous solution was added to the solution, and the solution was extracted by chloroform, dried by anhydrous sodium sulfate, pumping filtered, and then the filtrate was collected and the solvent was rotary evaporated off. Finally the raw product was subjected to silica gel column chromatography separation with petroleum ether: ethyl acetate (v/v=15:1) as eluent to obtain the solid powder 2,7-bis(4,4,5,5-tetramethyl-1,3,2-dioxaborolan-2-yl)-9,9-didecylfluorene, the yield of the product was 71%. GC-MS (EI-m/z): 699 (M⁺).

Secondly, the preparation of 4,7-bis(5′-bromo-4′-hexyl-2′-thienyl)-5,6-bis tetradecyloxy-2,1,3-benzothiadiazole:

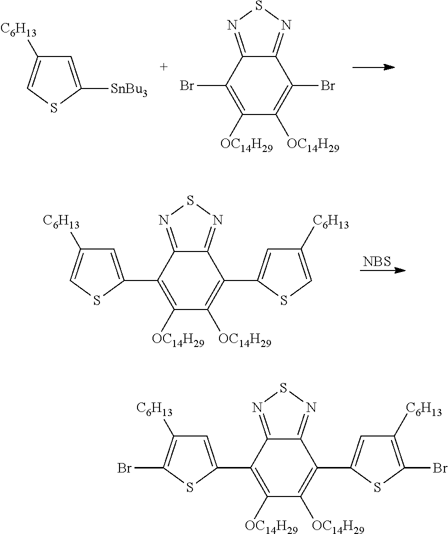

1 mmol of 4,7-dibromo-5,6-bis tetradecyloxy-2,1,3-benzothiopyrano oxadiazole and 2.2 mmol of 4-hexyl-2-tributyltin tin thiophene were dissolved in anhydrous toluene solvent, and then 0.03 mmol of tetrakis (triphenylphosphine) palladium was added, the solution was refluxed and reacted over night under the protection of nitrogen. After the solution cooled down, the precipitation deposited in methanol solvent, 4,7-bis(4′-hexyl-2′-thienyl)-5,6-bis tetradecyloxy-2,1,3-benzothiadiazole was separated by silica gel column chromatography, the yield of the product was 68%. GC-MS (EI-m/z): 893 (M⁺).

1 mmol of 4,7-bis(4′-hexyl-2′-thienyl)-5,6-bis tetradecyloxy-2,1,3-benzothiadiazole and 2.3 mmol of N-bromosuccinimide (NBS) were dissolved in 300 ml chloroform solvent, the solution was added to the 2-neck flask that was protected by argon and stirred constantly, the reaction lasted for 50 hours in dark at room temperature. After the product was subjected to after-treatment, vacuum dried and silica gel column chromatography, the solid powder 4,7-bis(5′-bromo-4′-hexyl-2′-thienyl)-5,6-bis tetradecyloxy-2,1,3-benzothiadiazole was obtained, the yield of the product was 72%. GC-MS (EI-m/z): 1051 (M⁺).

Thirdly, the preparation of the compounds with the following formulas.

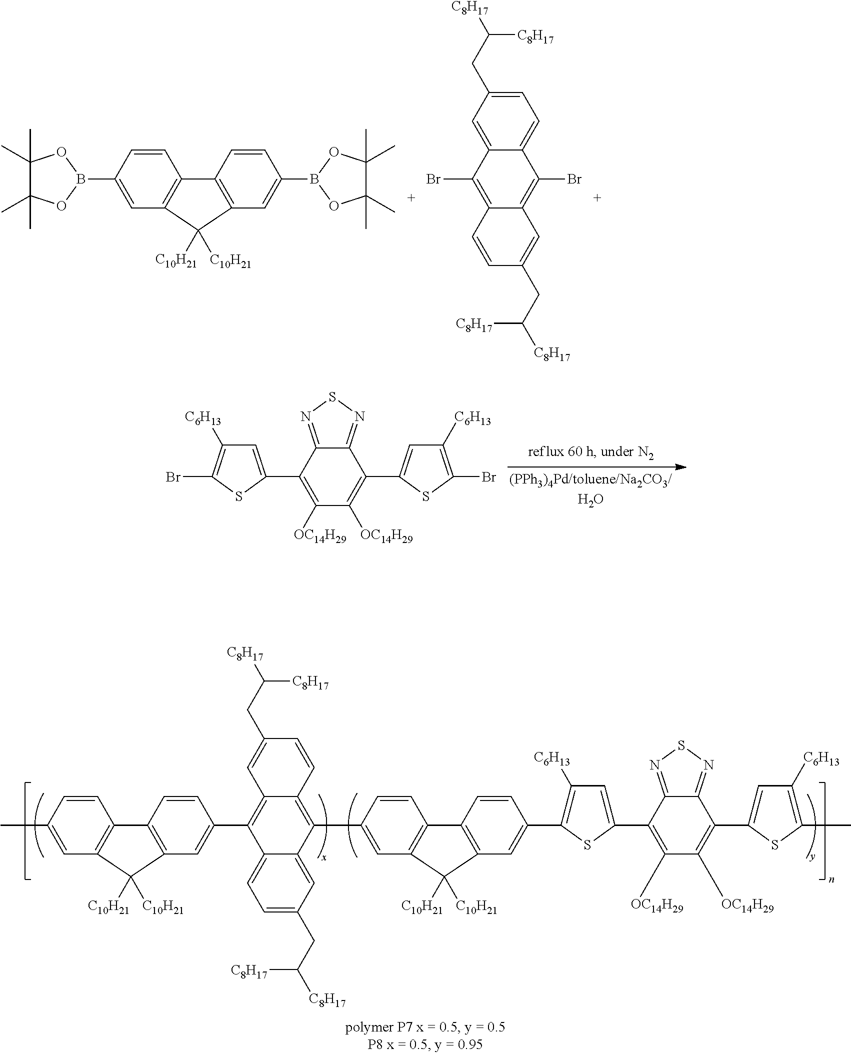

The Preparation of P7

1 mmol of 2,7-bis(4,4,5,5-tetramethyl-1,3,2-dioxaborolan-2-yl)-9,9-dioctylfluorene, 0.5 mmol of 9,10-dibromo-2,6-bis(2-octyl decyl) anthracene, 0.5 mmol of 4,7-bis(5′-bromo-4′-hexyl-2′-thienyl)-5,6-bis tetradecyloxy-2,1,3-benzothiadiazole, 0.025 mmol of tetrakis (triphenylphosphine) palladium, 10 ml of 2 mol/L Na₂CO₃ aqueous solution and 40 ml of toluene solvent were added to the reactor, the reaction system was kept in oxygen-free condition by purging N₂ and vacuum pumping repeatedly, the reaction lasted for 60 hours at 88° C.

After 60 hours, the deionized water and toluene were added to the reactor to extract the polymer, the organic phase was extracted, and the polymer/toluene was distilled to a little under reduced pressure, and then added the organic phase dropwise to 300 ml of anhydrous methanol with stirring constantly, and the solid was precipitated from the solution, the solid was pumping filtrated and dried to obtain the solid powder. And then the solid powder was dissolved in chloroform and purified by column chromatography of neutral alumina, after the catalyst tetrakis (triphenylphosphine) palladium was removed, the volume of the polymer/chloroform solution was reduced to about 5 ml by rotary evaporation, the solution was added dropwise to the methanol solvent and stirred several hours, and then the polymer P7 was collected and dried. The polymer was extracted by Soxhlet extraction, sequentially the monodispersity of the polymer molecular weight of the polymer was improved.

The purified polymer P7 was subject to GPC measurement, the number average molecular weight Mn≈59800, polymer monodisperse was 2.57.

The Preparation of P8

1 mmol of 2,7-bis(4,4,5,5-tetramethyl-1,3,2-dioxaborolan-2-yl)-9,9-dioctylfluorene, 0.05 mmol of 9,10-dibromo-2,6-bis(2-octyl decyl) anthracene and 0.95 mmol of 4,7-bis(5′-bromo-4′-hexyl-2′-thienyl)-5,6-bis tetradecyloxy-2,1,3-benzothiadiazole were added to the reactor, the amount of other materials added, reaction conditions and post-treatment methods were similar to the preparation of P7, the polymer P8 was obtained finally. The purified polymer P8 was subject to GPC measurement, the number average molecular weight Mn≈61400, polymer monodisperse was 2.03.

The following specific embodiments were the applications of the polymer containing units of fluorene, anthracene and benzothiadiazole in the field of polymer solar cells, organic electroluminescent devices, organic field effect transistor, organic light storage, organic nonlinear material, organic laser material, and so on.

### Example 5

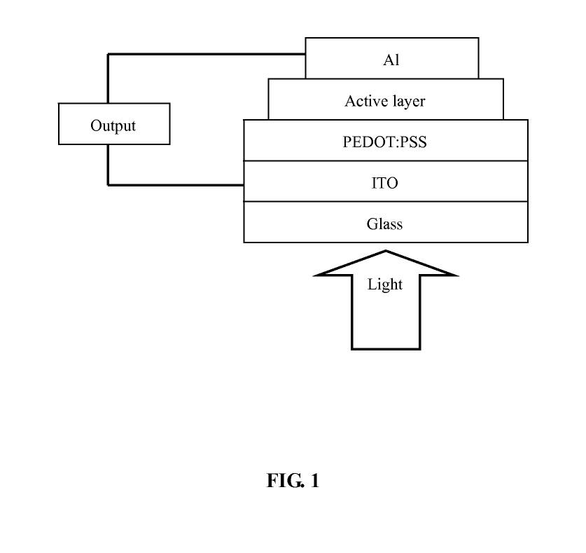

The structure of a kind of solar cell device was shown in FIG. 1. ITO glass (indium tin oxide glass) was used as substrate in the present embodiment, and ITO (indium tin oxide) was used as conductive layer. Polymer was the polymer P1 of the embodiment 1.

The structure of the solar cell device was as follows: glass/ITO/PEDOT:PSS/active layer/Al; wherein the material of the active layer was mixture which included [6,6]-phenyl-C61-butyric acid methyl ester as electron donor materials and the polymer containing units of fluorene, anthracene and benzothiadiazole as electron acceptor materials; ITO was indium tin oxide that the sheet resistance of the indium tin oxide was 10 to 20Ω/□, PEDOT was poly 3,4-ethylenedioxy thiophene, PSS was polystyrene sulfonate.

The fabrication process of the solar cell device was as follows:

the ITO glass was ultrasonic cleaned and treated with an oxygen-Plasma, and then the PEDOT: PSS layer as modification was coated to the ITO surface;
the active layer was coated on the described PEDOT: PSS layer by spin coating technology, the materials of active layer included [6,6]-phenyl-C61-butyric acid methyl ester as electron donor materials and the polymer containing units of fluorene, anthracene and benzothiadiazole as electron acceptor materials;
metal aluminum was evaporated onto the surface of the described active layer under vacuum condition, the metal aluminum layer was formed as cathode, the described organic solar cell device was obtained. In this embodiment, the thickness of the metal aluminum layer was 170 nm, in other embodiments, the thickness of the metal aluminum layer might be 30 nm, 130 nm, 60 nm.

In this embodiment, the solar cell device was kept 4 hours in 110 degrees Celsius under sealed condition, and then cooled to room temperature, after the device annealed, the arranged order and tacticity within the groups and molecular chains of the molecule were effectively increased, the mobility and the rate of transmission speed of the carriers also increased, and then the photoelectric conversion efficiency of the solar cell device was improved.

### Example 6

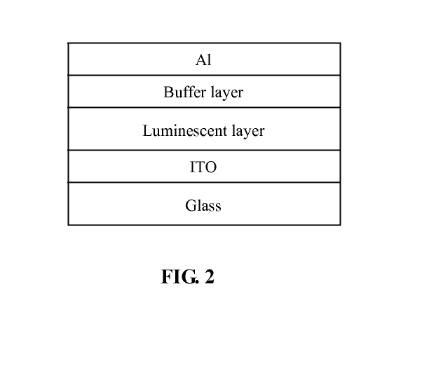

The structure of a kind of organic electroluminescent device was shown in FIG. 2. ITO glass (indium tin oxide glass) was used as substrate in the present embodiment, and ITO (indium tin oxide) was used as conductive layer, polymer was the polymer P1 of the embodiment 1.

The structure of the organic electroluminescent device was as follows: glass/ITO/luminescent layer/buffer layer/Al; wherein the material of the luminescent layer was the polymer containing units of fluorene, anthracene and benzothiadiazole; the material of the buffer layer was LiF; ITO was indium tin oxide that the sheet resistance of the indium tin oxide was 10-20Ω/□, PEDOT was poly 3,4-ethylenedioxy thiophene, PSS was polystyrene sulfonate.

The fabrication process of the organic electroluminescent device was as follows:

the ITO glass was ultrasonic cleaned and treated with an oxygen-Plasma, and then the polymer containing units of fluorene, anthracene and benzothiadiazole was coated onto the ITO surface and formed as luminescent layer;
the LiF was evaporated onto the surface of the described luminescent layer and formed as buffer layer under vacuum condition;
metal aluminum was evaporated onto the surface of the described buffer layer under vacuum condition, the metal aluminum layer was formed as cathode, the organic electroluminescent device was obtained. In this embodiment, the thickness of the metal aluminum layer was 170 nm, in other embodiments, the thickness of the metal aluminum layer might be 30 nm, 130 nm, 60 nm.

### Example 7

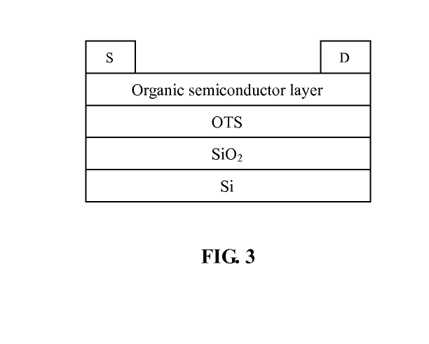

The structure of a kind of organic field-effect transistor was shown in FIG. 3. Highly doped silicon wafer was used as substrate in the present embodiment, polymer was the polymer P1 of the embodiment 1.

The structure of the organic field-effect transistor was as follows:

Si/SiO₂/OTS/organic semiconductor layer/source electrode (S) and drain electrode (D); wherein the thickness of the SiO₂ with function of insulation was 500 nm; OTS was octadecyltrichlorosilane; the material of the organic semiconductor layer was the polymer containing units of fluorene, anthracene and benzothiadiazole; the source electrode (S) and the drain electrode (D) were made of gold.

The fabrication process of the organic field-effect transistor was as follows:

the doped silicon wafer substrate was cleaned, the SiO₂ layer with the function of insulation was deposited on the surface of the substrate;
the OTS was coated on the surface of the SiO₂ insulation layer and formed as OTS layer;
the polymer containing units of fluorene, anthracene and benzothiadiazole was coated onto the surface of the OTS layer and formed as organic semiconductor layer;
the gold source electrode and the gold drain electrode were disposed on the organic semiconductor layer, the organic field-effect transistor was obtained.

It should be understood that the embodiments described above only expressed several implement patterns, and the description is much specific and detailed, but those descriptions can't be used to limit the present disclosure. It should be noted that for those of ordinary skill in the art, under the premise of without departing from the inventive concept, may be made a number of deformation and improved, which all belong to the scope of protection of the present invention. Therefore, the scope of protection of the invention patent should be subject to the appended claims.

1. A polymer containing units of fluorene, anthracene and benzothiadiazole, represented by the following formula: 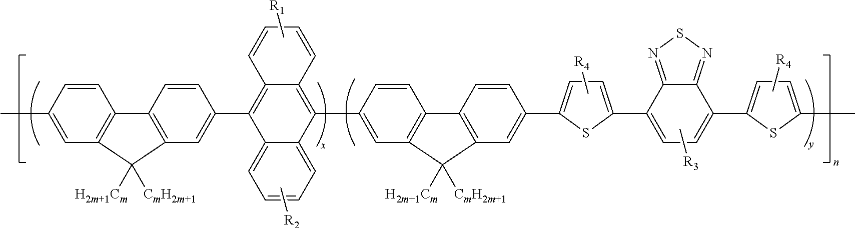
wherein n represents an integer between 1 and 200, m represents an integer between 1 and 20;
x, y are positive real numbers, and x+y=1;
R₁, R₂ represent H, halogen, cyano, C₁ to C₄₀ alkyl, C₁ to C₄₀ aryl or C₁ to C₄₀ heteroaryl;
R₃, R₄ represent H, halogen, cyano, C₁ to C₄₀ alkyl, C₁ to C₄₀ alkoxy, C₆ to C₄₀ aryl, C₆ to C₄₀ aralkyl or C₆ to C₄₀ arylalkoxy.

2. A preparation method of the polymer according to claim 1, comprising the following steps:
S11, providing compounds A, B and C represented by the following formulas, respectively, 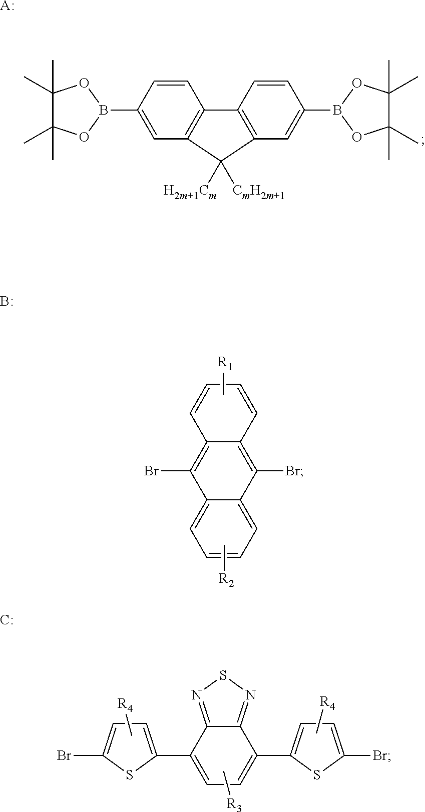
wherein m represents an integer between 1 and 20;
S12, subjecting compounds A, B and C to a Suzuki coupling reaction in the presence of organic solvent, catalyst and alkaline solution under the condition of oxygen-free environment to obtain the polymer containing units of fluorene, anthracene and benzothiadiazole with the following formula: 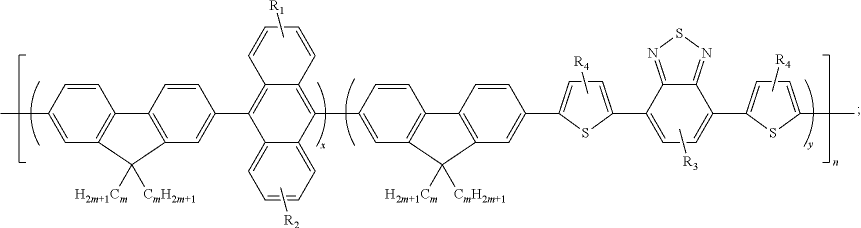
wherein n represents an integer between 1 and 200; m represents an integer between 1 and 20;
x, y are positive real numbers, and x+y=1;
R₁, R₂ represent H, halogen, cyano, C₁ to C₄₀ alkyl, C₁ to C₄₀ aryl or C₁ to C₄₀ heteroaryl;
R₃, R₄ represent H, halogen, cyano, C₁ to C₄₀ alkyl, C₁ to C₄₀ alkoxy, C₆ to C₄₀ aryl, C₆ to C₄₀ aralkyl or C₆ to C₄₀ arylalkoxy.

3. The preparation method according to claim 2, wherein in step S11, the compound A is prepared by the following steps:
providing compounds D and E represented by the following formulas, respectively, 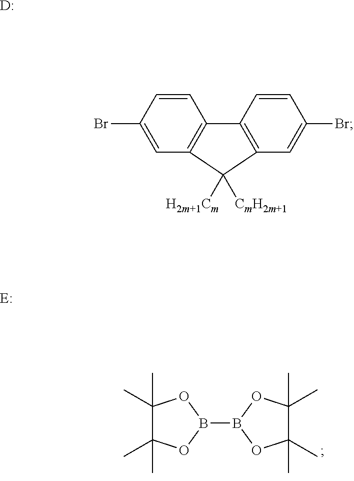
wherein m represents an integer between 1 and 20;
adding compound D to solvent under conditions of anhydrous and oxygen-free environment at a temperature of −70° C. to −85° C., adding n-butyl lithium according to a molar ratio of the n-butyl lithium to the compound D of 2:1 to 4:1, stirring for 2 hours; the solvent is at least one selected from the group consisting of tetrahydrofuran, diethyl ether, dichloromethane, chloroform, and ethyl acetate;
adding compound E according to a molar ratio of the compound E to the compound D of 2:1 to 4:1, raising the temperature to room temperature, reacting for 12 to 48 hours to obtain compound A represented by the following formula: 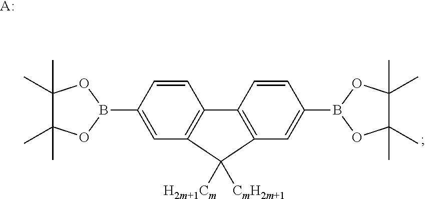
wherein m represents an integer between 1 and 20.

4. The preparation method according to claim 2, wherein in step S12,
the added amount of the catalyst is 0.5% to 10% of a molar amount of the compound A;
the catalyst is organic palladium catalyst or a mixture of organic palladium and organic phosphine ligand.

5. The preparation method according to claim 4, wherein the molar ratio of the organic palladium to the organic phosphine ligand is 1:2 to 1:20 in the mixture of organic palladium and organic phosphine ligand.

6. The preparation method according to claim 4, wherein the organic palladium is Pd₂(dba)₃, Pd(PPh₃)₄ or Pd(PPh₃)₂Cl₂; the organic phosphine ligand is P(o-Tol)₃.

7. The preparation method according to claim 2, further comprising: purifying the obtained polymer, wherein the purification steps comprise:
S13, adding deionized water and toluene to the polymer obtained in the step S12 to extract the polymer, extracting the organic phase, and distilling the organic phase under reduced pressure, and then adding the organic phase dropwise to the anhydrous methanol, stirring constantly, and then depositing the solid from the solution, after pumping filtrating and drying to obtain the solid powder, dissolving the solid powder in chloroform and then purifying by column chromatography of neutral alumina, after removing the catalyst and rotary evaporating the solution, and then adding dropwise to the methanol solvent and stirring, finally extracted by Soxhlet extraction to obtain a purified polymer.

8. (canceled)

9. (canceled)

10. (canceled)

11. The polymer according to claim 1, wherein R₃, R₄ represent H.

12. The polymer according to claim 11, wherein R₁, R₂ represent H.

13. The polymer according to claim 11, wherein R₁, R₂ represent C₁₇ alkyl.

14. The polymer according to claim 1, wherein R₁, R₂ represent C₁₇ alkyl.

15. The polymer according to claim 14, wherein R₃ represents H, R₄ represents C₆ alkyl.

16. The preparation method according to claim 2, wherein in step S12, the solvent is at least one selected from the group consisting of toluene, ethylene glycol, dimethyl ether, tetrahydrofuran, diethyl ether, dichloromethane, chloroform and ethyl acetate.

17. The preparation method according to claim 2, wherein in step S12, the added amount of the alkali solution is 5 to 10 times of a molar amount of the compound A;
the alkali solution is NaOH aqueous solution, Na₂CO₃ aqueous solution, NaHCO₃ aqueous solution or tetraethyl ammonium hydroxide aqueous solution.

18. The preparation method according to claim 2, wherein in step S12, the temperature of the Suzuki coupling reaction is 60 to 100° C., the reaction time is 12 to 72 hours.

19. The preparation method according to claim 5, wherein the organic palladium is Pd₂(dba)₃, Pd(PPh₃)₄ or Pd(PPh₃)₂Cl₂;
the organic phosphine ligand is P(o-Tol)₃.

20. The application of the polymer according to claim 1 in fields of solar cell device, organic electroluminescent device and organic field-effect transistor.
